(19) United States
(12) Patent Application Publication
(10) Pub. No.: US 2010/0244279 A1
(43) Pub. Date: Sep. 30, 2010

(54) Liquid resin composition for underfill, flip-chip mounted body and method for manufacturing the same

(75) Inventors: Masaaki Hoshiyama, Niigata-shi (JP); Masahiro Hasegawa, Niigata-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: NAMICS CORPORATION, Niigata-shi (JP)

(21) Appl. No.: 12/798,142

(22) Filed: Mar. 30, 2010

(30) Foreign Application Priority Data
Mar. 31, 2009 (JP) 2009-087286

(51) Int. Cl. H01L 23/16; C08L 63/00; H01L 21/56

(52) U.S. Cl. 257/778; 523/400; 438/124; 257/E23.135; 257/E21.503

(57) ABSTRACT

The invention relates to a liquid resin composition for underfill comprising (A) an epoxy resin, (B) an amine-based curing agent, and (C) an inorganic filler, a viscosity at a temperature of 25° C. being 1 to 150 Pa·s, and a time required for the viscosity to become 1 Pa·s at a temperature of 100° C. being 40 to 180 minutes.

### BACKGROUND OF THE INVENTION

1. Field of the Invention

The present invention relates to a liquid resin composition for underfill to be used in combination with a flip-chip bonding, a flip-chip mounted body comprising the liquid resin composition for underfill, and a method for manufacturing the mounted body. More particularly, the present invention relates to a liquid resin composition for underfill to be used when underfill process is performed under vacuum.

2. Description of the Related Art

Recently, flip-chip bonding is used as a method for mounting semiconductor chips that can meet the needs for higher density and higher frequency wiring of electronic devices. In flip-chip bonding, the gap between a semiconductor chip and a substrate is generally sealed with a material called underfill.

Typically, in an underfill process, a liquid resin composition with a low viscosity is applied to one side or two sides of a semiconductor chip when filling an underfill into the gap between the semiconductor chip and the substrate. The liquid resin composition with a low viscosity then flows into the gap between the semiconductor chip and the substrate by capillary action.

Due to further increase in bump density in more recent flip chips, there has arisen the problem that air bubbles remain in the underfill during the aforementioned underfill process. In order to solve this problem, a method in which a liquid resin composition is applied to the entire peripheral area of a semiconductor chip in a vacuum atmosphere, and then the degree of vacuum of the vacuum atmosphere is lowered or the vacuum atmosphere is turned to normal atmospheric-pressure atmosphere so as to fill the composition by the difference in pressure (hereinafter referred to as “the vacuum method”) (Patent Document 1: Japanese Laid-open Patent [Kokai] Publication No. 11-297902) is proposed.

In employing this vacuum method, a process of applying a liquid resin composition in a heated atmosphere of about 70 to 110° C. to reduce the manufacturing time required per flip-chip mounted body is being studied. In this process, such application may take 5 to 120 minutes for treating a number of semiconductor chips at one time.

Furthermore, as another mode of the vacuum method, also being considered is a method in which a liquid resin composition is applied to the entire peripheral area of a semiconductor chip in an atmospheric-pressure atmosphere, and then the pressure is reduced to a vacuum atmosphere, thereafter, the degree of vacuum of the vacuum atmosphere is lowered, or the vacuum atmosphere is changed to a normal atmospheric-pressure atmosphere for filling the composition by the difference in pressure. A process for applying a liquid resin composition in a heated atmosphere is also being considered here.

Currently used resin compositions for underfill, however, are those with a low viscosity in order that they flow by capillary action into the gap between a semiconductor chip and a substrate. When they are used for the vacuum method, the following problems arise during the application in a heated atmosphere in about 5 to 120 minutes: (1) the resin composition for underfill partially volatizes and bubbles; and (2) the resin composition for underfill starts to cure, with the result that the resin composition does not sufficiently flow into the gap between a semiconductor chip and a substrate, even if the degree of vacuum is lowered, or the pressure is turned to normal atmospheric-pressure atmosphere after application.

### SUMMARY OF THE INVENTION

An object of the present invention is to provide a resin composition for underfill capable of being filled into the gap between a semiconductor chip and a substrate by the vacuum method even after having been kept in a heated atmosphere. In particular, to provide a resin composition for underfill capable of being used in the vacuum method in which a resin composition for underfill is applied in a reduced and heated atmosphere.

The present invention relates to a liquid resin composition for underfill in which the aforementioned problems were solved by having the following constitution.

(1) A liquid resin composition for underfill comprising (A) an epoxy resin, (B) an amine-based curing agent, and (C) an inorganic filler, a viscosity at a temperature of 25° C. being 1 to 150 Pa·s, and a time required for the viscosity to become 1 Pa·s at a temperature of 100° C. being 40 to 180 minutes.
(2) The liquid resin composition for underfill according to (1) above, wherein the time required for the viscosity to become 1 Pa·s at a pressure of 100 Pa and at a temperature of 100° C. is 40 to 180 minutes.
(3) The liquid resin composition for underfill according to (1) above, wherein an average volatilization rate when kept for two hours at a pressure of 100 Pa and at a temperature of 100° C. is 0 to 1.3 mass %/hour.
(4) The liquid resin composition for underfill according to (2) above, wherein the average volatilization rate when kept for two hours at a pressure of 100 Pa and at a temperature of 100° C. is 0 to 1.3 mass %/hour.
(5) The liquid resin composition for underfill according to (1) above, wherein the average volatilization rate of Component (B) when kept for two hours at a pressure of 100 Pa and at a temperature of 100° C. is 0 to 10 mass %/hour.
(6) The liquid resin composition for underfill according to (2) above, wherein the average volatilization rate of Component (B) when kept for two hours at a pressure of 100 Pa and at a temperature of 100° C. is 0 to 10 mass %/hour.
(7) The liquid resin composition for underfill according to (1) above, wherein Component (B) comprises an aromatic amine compound having one aromatic ring and/or an aromatic amine compound having two aromatic rings, and the aromatic amine compound having two benzene rings is 50 to 100 parts by mass with respect to the total 100 parts by mass of the aromatic amine compound.
(8) The liquid resin composition for underfill according to (1) above, wherein Component (B) comprises an aromatic amine compound having one aromatic ring and/or an aromatic amine compound having two aromatic rings, and the aromatic amine compound having two benzene rings is 50 to 100 parts by mass with respect to the total 100 parts by mass of the aromatic amine compound, and the time required for the viscosity to become 1 Pa·s at a pressure of 100 Pa and at a temperature of 100° C., is 40 to 180 minutes.
(9) The liquid resin composition for underfill according to (7) above, wherein the average volatilization rate is 0 to 1.3 mass %/hour when kept for two hours at a pressure of 100 Pa and at a temperature of 100° C.
(10) The liquid resin composition for underfill according to (8) above, wherein the average volatilization rate when kept for two hours at a pressure of 100 Pa and at a temperature of 100° C. is 0 to 1.3 mass %/hour.
(11) The liquid resin composition for underfill according to (7) above, wherein the average volatilization rate of Component (B) when kept for two hours at a pressure of 100 Pa and at a temperature of 100° C. is 0 to 10 mass %/hour.
(12) The liquid resin composition for underfill according to (8) above, wherein the average volatilization rate of Component (B) when kept for two hours at a pressure of 100 Pa and at a temperature of 100° C. is 0 to 10 mass %/hour.
(13) The liquid resin composition for underfill according to (1) above, wherein Component (A) is at least one selected from the group consisting of a bisphenol F type epoxy resin and a naphthalene type epoxy resin, and the time required for the viscosity to become 1 Pa·s at a pressure of 100 Pa and at a temperature of 100° C. is 40 to 180 minutes.
(14) The liquid resin composition for underfill according to (1) above, wherein Component (A) is at least one selected from the group consisting of a bisphenol F type epoxy resin and a naphthalene type epoxy resin, Component (B) comprises an aromatic amine compound having one aromatic ring and/or an aromatic amine compound having two aromatic rings, and the aromatic amine compound having two benzene rings is 50 to 100 parts by mass with respect to the total 100 parts by mass of the aromatic amine compound.
(15) The liquid resin composition for underfill according to (1) above, wherein Component (A) is at least one selected from the group consisting of a bisphenol F type epoxy resin and a naphthalene type epoxy resin, Component (B) comprises an aromatic amine compound having one aromatic ring and/or an aromatic amine compound having two aromatic rings, the aromatic amine compound having two benzene rings is 50 to 100 parts by mass with respect to the total 100 parts by mass of the aromatic amine compound, and the time required for the viscosity to become 1 Pa·s at a pressure of 100 Pa and at a temperature of 100° C. is 40 to 180 minutes.
(16) The liquid resin composition for underfill according to (2) above, comprising 30 to 120 parts by mass of Component (B) and 160 to 400 parts by mass of Component (C) with respect to 100 parts by mass of Component (A).
(17) The liquid resin composition for underfill according to (7) above, comprising 30 to 120 parts by mass of Component (B) and 160 to 400 parts by mass of Component (C) with respect to 100 parts by mass of Component (A).
(18) The liquid resin composition for underfill according to (8) above, comprising 30 to 120 parts by mass of Component (B) and 160 to 400 parts by mass of Component (C) with respect to 100 parts by mass of Component (A).
(19) A flip-chip mounted body sealed with any of the liquid resin composition for underfill as set forth in (8) above.
(20) A method for manufacturing a flip-chip mounted body sealed with the liquid resin composition for underfill as set forth in (19) above.

According to the present invention (1), it is possible to obtain a liquid resin composition for underfill capable of being filled into the gap between a semiconductor chip and a substrate after having been kept in a heated atmosphere.

According to the present invention (2), it is possible to obtain a liquid resin composition for underfill that can be used in the vacuum method, because the composition can be filled into the gap between a semiconductor chip and a substrate after having been kept in a reduced and heated atmosphere.

According to the present invention (3) or (5), it is possible to obtain a liquid resin composition for underfill whose bubble formation is inhibited even in a heated vacuum atmosphere.

According to the present invention (19), it is possible to obtain a flip-chip mounted body sealed with the liquid resin composition for underfill of the present invention (8).

According to the present invention (9), it is possible to easily obtain a flip-chip mounted body sealed with the liquid resin compositions for underfill of the present inventions (1) to (7).

### BRIEF DESCRIPTION OF THE DRAWINGS

FIG. 1 is a schematic view showing an example of a flip-chip mounted body.

FIGS. 2A to 2E are schematic views showing an example of a method for manufacturing a flip-chip mounted body by the vacuum method.

FIG. 3 is a graph showing the influence on volatilization rate of the parts by mass of an amine-based curing agent A with respect to the total 100 parts by mass of the amine-based curing agent A and an amine-based curing agent B.

### DESCRIPTION OF THE PREFERRED EMBODIMENTS

The liquid resin composition for underfill of the present invention is a composition comprising (A) an epoxy resin, (B) an amine-based curing agent, and (C) an inorganic filler, characterized in that the viscosity at a temperature of 25° C. is 1 to 150 Pa·s, and the time required for the viscosity to become 1 Pa·s at a temperature of 100° C. is 40 to 180 minutes.

Examples of Component (A) include a bisphenol A type epoxy resin, a brominated bisphenol A type epoxy resin, a bisphenol F type epoxy resin, a naphthalene type epoxy resin, an biphenyl type epoxy resin, an novolac type epoxy resin, an alicyclic epoxy resin, an ether based or polyether based epoxy resin, and an oxirane ring-containing epoxy resin; and preferred are a bisphenol F type epoxy resin and a naphthalene type epoxy resin in view of the viscosity of the liquid resin composition for underfill.

The bisphenol F type epoxy resin is preferably represented by formula (1):

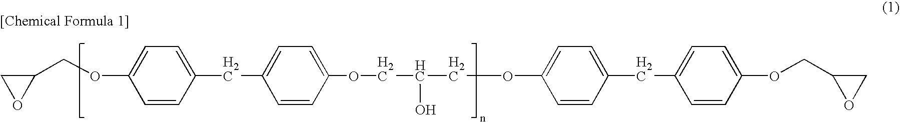

wherein, n represents a mean value, preferably 0 to 10, particularly preferably 0 to 4. The epoxy equivalent is preferably 160 to 900 g/eq.

The naphthalene type epoxy resin is preferably represented by formula (2) or (3):

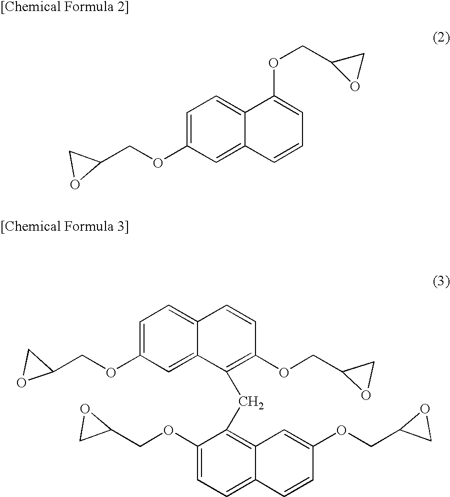

Component (A) may be used alone or in combination of two or more.

Examples of Component (B) include compounds such as aliphatic polyamines; aromatic amines; modified polyamines such as polyaminoamide, polyaminoimide, polyaminoester and polyaminourea; and tertiary amine base; imidazole base; hydrazide base; dicyanamide base; and melamine base compounds, and aromatic amine base compounds are preferable.

It is more preferred that the aromatic amine-base compound include an aromatic amine compound having one aromatic ring and/or an aromatic amine compound having two aromatic rings. Here, it is expected that an aromatic amine compound having one aromatic ring can prevent curing of a liquid resin composition for underfill during its application in a heated atmosphere, and can also cure the liquid resin composition for underfill even after the composition having been kept in a heated atmosphere. Furthermore, it is expected that an aromatic amine compound having two aromatic rings can inhibit bubble formation during its application in a heated atmosphere, and can cure the liquid resin composition for underfill even after the composition having been kept in a heated atmosphere.

As the aromatic amine compound having one aromatic ring, there can be mentioned meta-phenylenediamines and the like, and preferred are those represented by formula (4) or formula (5):

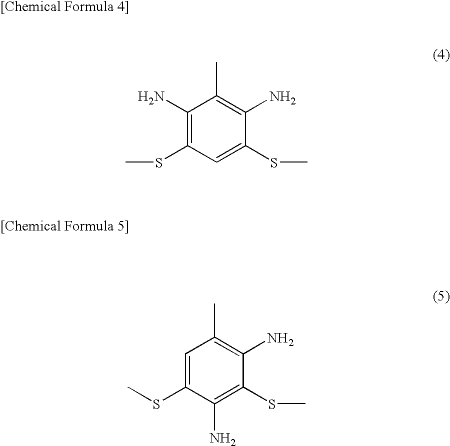

As the aromatic amine compound having two aromatic rings, there can be mentioned diaminodiphenylmethanes, diaminodiphenyl sulfones, and the like, and those represented by formula (6) or (7):

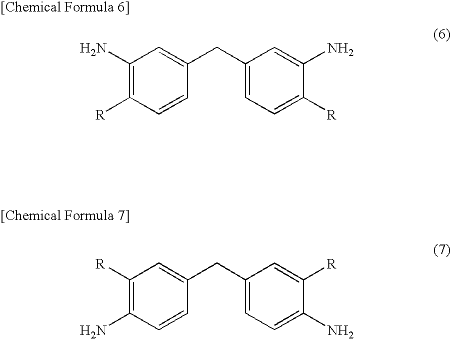

wherein, R represents hydrogen or an alkyl group having a carbon number of 1 to 5 are preferable, and those represented by formula (6) or formula (7) wherein R is an alkyl group having a carbon number of 2 is more preferable.

As for Component (B), those comprising an aromatic amine compound having one aromatic ring and/or an aromatic amine compound having two aromatic rings in which the aromatic amine compound having two benzene rings is 50 to 100 parts by mass with respect to the total 100 parts by mass of the aromatic amine compound(s) are more preferable in that they can inhibit bubble formation during application in a heated atmosphere, and prevent curing of the liquid resin composition for underfill during application in a heated atmosphere, and further in that they can cure the liquid resin composition for underfill even after the composition having been kept in a heated atmosphere. Here, the mass ratio of the aromatic amine compound having one aromatic ring to the aromatic amine compound having two aromatic rings in the aromatic amine compound is measured by GC-MS.

Furthermore, it is preferred that the average volatilization rate of Component (B) when kept for two hours with the pressure of Component (B) being 50 to 200 Pa (preferably 100 Pa) at a temperature of 100° C., be 0 to 10 mass %/hour, in view of the inhibition of bubble formation in the liquid resin composition for underfill during application in a heated atmosphere. As a method for reducing the volatilization rate of Component (B), a method known to a person skilled in the art, such as distillation of Component (B), may be used. Here, while the volatilization rate is obtained by mass measurement at room temperature after placing Component (B) in a dryer or the like and keeping it therein for two hours at a pressure of from 50 to 200 Pa (preferably 100 Pa) and at a temperature of 100° C., it may be measured by the TG method. Here, the pressure at the time of measurement may be controlled at an accuracy of ±100 Pa. Unless otherwise specified, the pressure is controlled with this accuracy in the present invention.

Component (B) may be used alone or in combination of two or more.

Examples of Component (C) include silica, alumina, silicon nitride, mica, and white carbon, and silica is preferable in view of the cost and the reduction in thermal expansion coefficient of the liquid resin composition for underfill after curing. As the silica, various ones used in this technical field such as amorphous silica, crystalline silica, fused silica, and pulverized silica can be used, and amorphous silica is preferable in view of the reduction in thermal expansion coefficient of the liquid resin composition for underfill after curing. The particle size of Component (C) is preferably 0.1 to 2.0 μm, and more preferably 0.1 to 1.0 μm in view of the filling property into the gap between a semiconductor chip and a substrate. Furthermore, the shape of Component (C) is not particularly limited, and spherical, scale, indeterminate form, and the like can be mentioned, and a spherical shape is preferable in view of the fluidity of the liquid resin composition for underfill.

Component (C) may be used alone or in combination of two or more.

The liquid resin composition for underfill of the present invention preferably comprises 30 to 120 parts by mass of Component (B) with respect to 100 parts by mass of Component (A), considering that Component (B) can inhibit bubble formation during application in a heated atmosphere, prevent curing of the liquid resin composition for underfill during application in a heated atmosphere, and cure the liquid resin composition for underfill even after the composition having been kept in a heated atmosphere.

Furthermore, the liquid resin composition for underfill preferably comprises 160 to 400 parts by mass of Component (C) with respect to 100 parts by mass of Component (A) in view of the fluidity of the liquid resin composition for underfill and the reduction in thermal expansion coefficient of the liquid resin composition for underfill after curing.

A pigment such as carbon black, a dye, a silane coupling agent, an antifoaming agent, an antioxidant, and other additives, and, additionally, an organic solvent and the like may be blended into the liquid resin composition for underfill of the present invention, where necessary, within the scope of not impairing the object of the present application. In particular, it is preferred that carbon black be added in order to prevent the liquid resin composition for underfill after curing from blocking light and inviting malfunction of IC chips, and that a silane coupling agent be added in order to enhance the wettability of Component (C) with the other components. It is preferred, however, that no organic solvent with a low boiling point be contained in the present invention in view of inhibiting bubble formation of the liquid resin composition for underfill during application in a heated atmosphere.

The liquid resin composition for underfill of the present invention may be obtained, for example, by stirring, melting, mixing, and dispersing Component (A) to Component (C) and other additives at the same time or separately, subjecting them, if necessary, to heat treatment. In particular, when Component (B) is solid, it is preferred that Component (B) be liquefied by heating beforehand and then mixed with Component (A), because when blended as it is, the viscosity of the resin increases, substantially impairing its workability. While the devices for mixing, stirring, and dispersing them are not particularly limited, a grinding mill (Raikai-ki) equipped with a stirrer and a heater; a triple roll mill; a ball mill; a planetary mixer; a bead mill, and the like can be used. Furthermore, these devices may be used suitably in combination.

The liquid resin composition for underfill of the present invention has a viscosity of from 1 to 150 Pa·s at a temperature of 25° C., and the time required for the viscosity to become 1 Pa·s at a temperature of 100° C. is 40 to 180 minutes. Here, the viscosity is measured by Rheometer (Model: MARS2) by HAAKE.

Furthermore, it is preferred, in the liquid resin composition for underfill, that the time required for the viscosity to become 1 Pa·s be 40 to 180 minutes at a pressure of 50 to 200 Pa (preferably 100 Pa) at a temperature of 100° C. Here, the viscosity is measured according to the following steps: putting the liquid resin composition for underfill into a vacuum dryer or the like, setting the pressure therein at 100±100 Pa, keeping the composition therein at 100° C. for 10 minutes, and then performing measurement using the aforementioned Rheometer. The time required for the viscosity to become 1 Pa·s is determined by repeating this measurement. It should be noted that in the present invention “vacuum” means a reduced pressure of 200 Pa or less.

Furthermore, it is preferred that the liquid resin composition for underfill has an average volatilization rate of 0 to 1.3 mass %/hour when kept for two hours at a pressure of 50 to 200 Pa and at a temperature of 100° C., in view of inhibition of bubble formation when the liquid resin composition for underfill is applied at a heated atmosphere. Here, the volatilization rate is obtained by mass measurement at room temperature of the liquid resin composition for underfill or the amine-based curing agent after putting it into an aluminum container of a given volume, and keeping the container on a hot plate at 100° C. that is placed in a desiccator for two hours at 100±100 Pa, but the measurement may be performed by the TG method.

Curing of the liquid resin composition for underfill of the present invention is preferably conducted at 150 to 165° C. for 90 to 150 minutes.

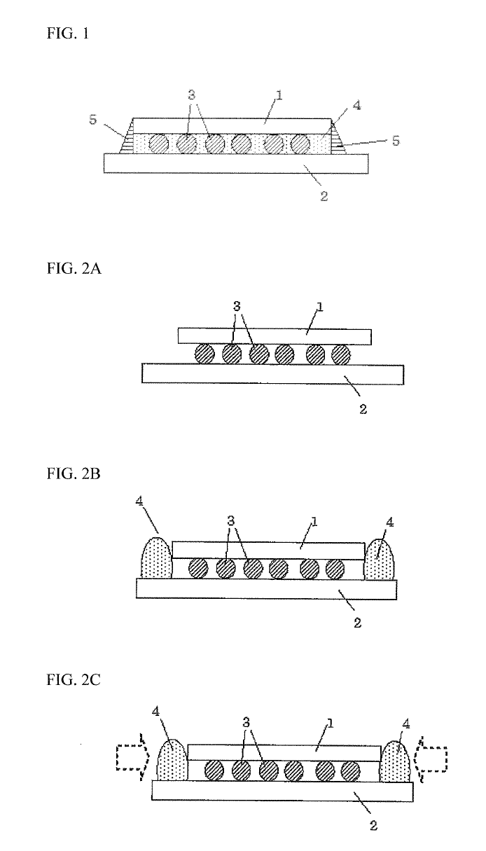

An example of a flip-chip mounted body used in the present invention is, as shown in FIG. 1, one comprising a semiconductor chip 1 mounted on the wiring pattern surface of a substrate 2 interposing a plurality of bumps 3 therebetween, the liquid resin composition for underfill 4 being filled in the gap between the semiconductor chip 1 and the substrate 2 and the gaps between the bumps 3, and the fillet 5 is formed on the sides thereof. Here, the liquid resin composition for underfill 4 of the present invention can be used also as a fillet 5, while it is particularly effective when used as an underfill agent.

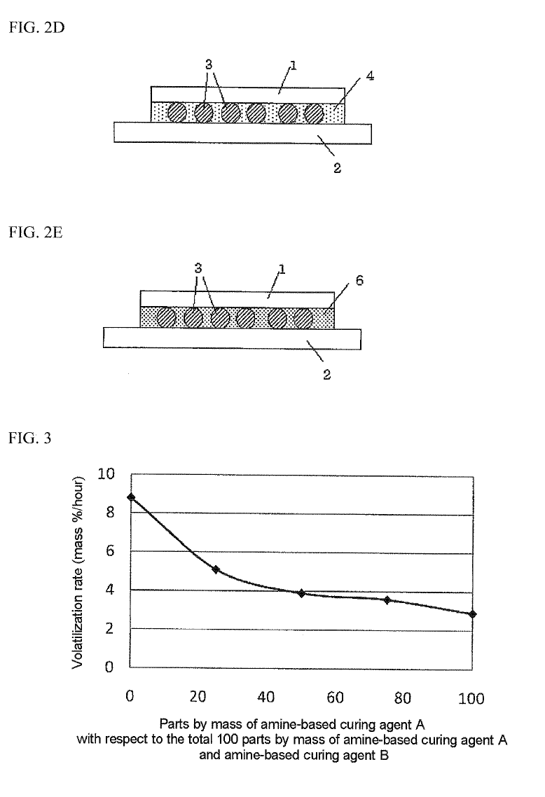

FIG. 2 shows an example of a method for manufacturing this flip-chip mounted body by the vacuum method. First, a semiconductor chip 2 joined to a substrate 1 interposing a bump 3 therebetween is prepared (FIG. 2A).

Next, the liquid resin composition for underfill 4 is applied to the entire peripheral area of the semiconductor chip 1 (FIG. 2B). At this time, the liquid resin composition may be applied to the entire peripheral areas of a plurality of semiconductor chips 2 to improve work efficiency over about 30 to 120 minutes in a heated atmosphere (e.g., 70 to 110° C.). Furthermore, the liquid resin composition may be applied under vacuum (e.g., at a pressure of from 50 to 200 Pa).

Next, when the application is performed under vacuum, the degree of vacuum of the vacuum atmosphere is lowered, or the vacuum atmosphere is changed to a normal atmospheric-pressure atmosphere to cause the liquid resin composition for underfill 4 to be filled into the gap between the semiconductor chip 1 and the substrate 2 by the difference in pressure (FIGS. 2C and 2D. Here, the arrow in FIG. 2C indicates the direction on which the differential pressure is applied). Furthermore, when the application is performed in an atmospheric-pressure atmosphere, the atmosphere of the semiconductor chip 1 or the like to which the liquid resin composition is applied, is changed into a vacuum atmosphere, and then the degree of vacuum of the vacuum atmosphere is lowered, or the vacuum atmosphere is returned to a normal atmospheric-pressure atmosphere to cause the liquid resin composition for underfill 4 to be filled therein by the difference in pressure. It should be noted that, in this case, when the applied semiconductor chip 1 or the like is placed in a vacuum atmosphere, the atmosphere around the bumps 3 passes through the liquid resin composition for underfill 4, so that the atmosphere around the bumps 3 become a vacuum atmosphere. Here, an air path is formed in the liquid resin composition for underfill 4 when the air passes, the entire peripheral area of the semiconductor chip 1 can thereafter be covered again by levelling, and the gap between the semiconductor chip 1 and the substrate 2 can be filled by the differential pressure.

The liquid resin composition for underfill 4 is then cured to produce the flip-chip mounted body (FIG. 2E). Here, as a substrate, an epoxy resin, a glass epoxy resin, a polyimide resin or the like may be mentioned, but not limited to them. As a bump, soldering alloys comprising tin, lead, copper, bismuth, silver, zinc, indium, or the like may be used, and lead-free soldering alloys are preferable from the environmental standpoint, but not limited to them.

In this manner, a flip-chip mounted body can be produced by the vacuum method when using the liquid resin composition for underfill of the present invention.

### EXAMPLES

The present invention will further be described by way of Examples, but is by no means limited thereto. In the following Examples, part(s) and % are given by weight unless otherwise indicated.

### Examples 1 to 6 and Comparative Examples 1 to 4

The liquid resin compositions for underfill were prepared according to the formulations as given in Table 1.

TABLE 1

| | | | | | | | | | Com- | Com- |
|---|---|---|---|---|---|---|---|---|---|---|
| | Ex- | Ex- | Ex- | Ex- | Ex- | Ex- | Comparative | Comparative | parative | parative |
| | ample 1 | ample 2 | ample 3 | ample 4 | ample 5 | ample 6 | Example 1 | Example 2 | Example 3 | Example 4 |
| Naphthalene type epoxy resin *1 | 0 | 11.9 | 11.9 | 11.9 | 17.1 | 11.9 | 19.2 | 21.2 | 19.2 | 20.0 |
| Bisphenol F type epoxy resin *2 | 24.0 | 18.6 | 18.6 | 18.6 | 2.5 | 18.6 | 0.5 | 0.5 | 0.5 | 4 |
| Amine-based curing agent A *3 | 10.3 | 6.4 | 9.6 | 10.2 | 0 | 3.2 | 0 | 0 | 0 | 10.3 |
| Amine-based curing agent B *4 | 0 | 6.4 | 3.2 | 2.6 | 14.8 | 9.6 | 0 | 0 | 0 | 0 |
| Acid anhydride-based curing agent A *5 | 0 | 0 | 0 | 0 | 0 | 0 | 19.1 | 17.1 | 0 | 0 |
| Acid anhydride-based curing agent B *6 | 0 | 0 | 0 | 0 | 0 | 0 | 0 | 0.0 | 19.1 | 0 |
| Curing accelerator *7 | 0 | 0 | 0 | 0 | 0 | 0 | 4.0 | 4.0 | 4 | 0 |
| Silane coupling agent *8 | 0.6 | 0.4 | 0.4 | 0.4 | 0.4 | 0.4 | 0.3 | 0.3 | 0.3 | 0.6 |
| Silica filler *9 | 65.1 | 56.3 | 56.3 | 56.3 | 65.2 | 56.3 | 56.8 | 56.9 | 56.9 | 65.1 |
| Total | 100.0 | 100.0 | 100.0 | 100.0 | 100.0 | 100.0 | 100.0 | 100.0 | 100.0 | 100.0 |

*1: Epicron HP4032D by DIC
*2: YDF-8170 by Tohto Kasei
*3: KAYAHARD HDAA by Nippon Kayaku: an aromatic amine compound having two aromatic rings
*4: A mixture of a compound of formula (4), a compound of formula (5), and a compound of formula (7) wherein R is C₂H₅ = 4:1:5
*5: jER Cure YH307 by Japan Epoxy Resin
*6: Epicron B650 by DIC
*7: 2,4-diamino-6-[2′-methylimidazolyl-(1′)]-ethyl-s-triazine isocyanuric acid adduct
*8: 3-glycidoxypropyltrimethoxysilane
*9: Average particle diameter: 0.6 μm

### Measurement of Initial Viscosity

The initial viscosity of 1 g of the obtained liquid resin composition for underfill was measured at 25° C. using Rheometer (Model number: MARS2) by HAAKE. The results are shown in Table 2.

### Measurement of Pot Life

Change in viscosity of 1 g of the liquid resin composition for underfill was measured at 100° C. using Rheometer (Model number: MARS2) by HAAKE. The time (minutes) required for the liquid resin composition for underfill to increase its viscosity to 1 Pa·s is referred to “pot life in atmosphere”. Furthermore, 1 g of the liquid resin composition for underfill was put into a vacuum dryer, and the pressure was set at 100±100 Pa, and the viscosity of the composition having been left at 100° C. for 10 minutes was determined by the aforementioned Rheometer. This measurement was repeated, and the time required for the viscosity to become 1 Pa·s or more is referred to “pot life in vacuum”. The results are shown in Table 2.

### Measurement of Volatilization Rate

Into a cylindrical aluminum container having a diameter of 5 cm was placed 3 g of the liquid resin composition for underfill or the curing agent, which was then left standing at a pressure of 100 Pa and at 100° C. for two hours, and then mass measurement was performed.

{(Mass before left standing)−(Mass after left standing)/(Mass before left standing)}×100/2} was regarded as the average volatilization rate (unit: mass %/hour). At this time, the pressure was controlled at 100±50 Pa. However, for the cases where the acid anhydride-based curing agents were used, mass measurement was conducted 30 minutes later to obtain the average volatilization rate, because they cure rapidly and cease to volatize at an earlier stage. In these cases, the “2” in the equation above was replaced by “0.5” for the calculation. The results are shown in Table 2. Furthermore, Table 3 shows the formulations of Reference Examples 1 to 7 in which curing agents were varied, and their respective volatilization rates. FIG. 3 shows the influence on the volatilization rate of the parts by mass of the amine-based curing agent A with respect to the total 100 parts by mass of the amine-based curing agent A and the amine-based curing agent B at this time.

### Void Test

Into a dispenser was placed 10 g of the liquid resin composition for underfill, and dispensing was performed in the vacuum dispenser (Model number: FS2500) by Toray Engineering set at a pressure of 130 Pa and at 100° C. The time during which dispensing was possible with no occurrence of voids was measured. At this time, the pressure was controlled at 130±5 Pa. The presence/absence of voids was observed by the naked eye. In the void test, the time during which no void occurs is preferably at least 60 minutes. The results are shown in Table 2.

### Bubble Formation Test

Into the vacuum dispenser (Model number: FS2500) by Toray Engineering was placed 5 g of the liquid resin composition for underfill, and the presence/absence of bubble formation when kept at a pressure of 130 Pa and at 100° C. for 30 minutes was observed by the naked eye. At this time, the pressure was controlled at 130±5 Pa. The results are shown in Table 2.

TABLE 2

| | | | | | | | Com- | Com- | Com- | Com- |
|---|---|---|---|---|---|---|---|---|---|---|
| | Ex- | Ex- | | | | | parative | parative | parative | parative |
| | ample 1 | ample 2 | Example 3 | Example 4 | Example 5 | Example 6 | Example 1 | Example 2 | Example 3 | Example 4 |
| Initial viscosity (Pa · s) | 60 | 45 | 50 | 40 | 35 | 40 | 60 | 50 | 15 | 180 |
| Pot life in atmosphere (min.) | 90 | 80 | 65 | 55 | 120 | 100 | 18 | 20 | 30 | 50 |
| Pot life in vacuum (min.) | 80 | 70 | 60 | 50 | 110 | 90 | 20 | 20 | 20 | 40 |
| Volatilization rate (mass %/hour) | 0.3 | 0.7 | 0.4 | 0.36 | 1.2 | 1.2 | 4.8 | 4.3 | 3.6 | 0.3 |
| Void test (min.) | 90 | 80 | 80 | 80 | 120 | 100 | 18 | 20 | 30 | 50 |
| Bubble formation | Not | Not | Not | Not | Not | Not | Observed | Observed | Observed | Not |
| | ob- | ob- | ob- | observed | observed | observed | | | | observed |
| | served | served | served | | | | | | | |

TABLE 3

| | Reference | Reference | Reference | Reference | Reference | Reference | Reference |
|---|---|---|---|---|---|---|---|
| | Example 1 | Example 2 | Example 3 | Example 4 | Example 5 | Example 6 | Example 7 |
| Amine-based curing agent A | 100 | 75 | 50 | 25 | 0 | 0 | 0 |
| Amine-based curing agent B | 0 | 25 | 50 | 75 | 100 | 0 | 0 |
| Acid anhydride-based curing | 0 | 0 | 0 | 0 | 0 | 100 | 0 |
| agent A | | | | | | | |
| Acid anhydride-based curing | 0 | 0 | 0 | 0 | 0 | 0 | 100 |
| agent B | | | | | | | |
| Volatilization rate | 2.9 | 3.6 | 3.9 | 5.1 | 8.8 | 95.0 | 95.0 |
| (mass %/hour) | | | | | | | |

As can be seen from Table 2, Examples 1 to 6 all showed good results in pot life, volatilization rate, void test, and bubble formation test, and, in particular, Examples 1 to 4 showed especially good results. Examples 5 and 6, which contain the amine-based curing agent B more than the amine-based curing agent A had a volatilization rate of 1.2 g/hour and a pot life of 120 minutes. In contrast thereto, Comparative Examples 1 to 3 containing an acid anhydride-based curing agent instead of an amine-based curing agent showed a shorter pot life, greater volatilization rate and earlier void generation, and formation of bubbles was observed in the bubble formation test. In Comparative Example 4, which had a high initial viscosity, the pot life in vacuum was shorter and the result of void test was 50 minutes.

As can be seen from Table 3, the volatilization rates in Reference Examples 1 to 5, which are amine-based curing agents, were less than those of the acid anhydride-based curing agents of Reference Examples 6 and 7. Furthermore, among amine-based curing agents, the volatilization rate of amine A having two aromatic rings was less than that of amine B, which is a mixture of amine having two aromatic rings and one aromatic ring. As can be seen from FIG. 2, when the amount of the amine-based curing agent A is less than 50 mass %, there is a tendency that the lesser the amount of the amine-based curing agent A, the greater the volatilization rate.

As explained above, the liquid resin composition for underfill of the present invention has a long pot life at a high temperature, a small volatilization rate under a reduced pressure and in a heated atmosphere, and is free of voids and bubbles, and thus is extremely suitable for the vacuum method.

What is claimed is:

1. A liquid resin composition for underfill comprising (A) an epoxy resin, (B) an amine-based curing agent, and (C) an inorganic filler, a viscosity at a temperature of 25° C. being 1 to 150 Pa·s, and a time required for the viscosity to become 1 Pa·s at a temperature of 100° C. being 40 to 180 minutes.

2. The liquid resin composition for underfill according to claim 1, wherein the time required for the viscosity to become 1 Pa·s at a pressure of 100 Pa and at a temperature of 100° C. is 40 to 180 minutes.

3. The liquid resin composition for underfill according to claim 1, wherein an average volatilization rate when kept for two hours at a pressure of 100 Pa and at a temperature of 100° C. is 0 to 1.3 mass %/hour.

4. The liquid resin composition for underfill according to claim 2, wherein the average volatilization rate when kept for two hours at a pressure of 100 Pa and at a temperature of 100° C. is 0 to 1.3 mass %/hour.

5. The liquid resin composition for underfill according to claim 1, wherein the average volatilization rate of Component (B) when kept for two hours at a pressure of 100 Pa and at a temperature of 100° C. is 0 to 10 mass %/hour.

6. The liquid resin composition for underfill according to claim 2, wherein the average volatilization rate of Component (B) when kept for two hours at a pressure of 100 Pa and at a temperature of 100° C. is 0 to 10 mass %/hour.

7. The liquid resin composition for underfill according to claim 1, wherein Component (B) comprises an aromatic amine compound having one aromatic ring and/or an aromatic amine compound having two aromatic rings, and the aromatic amine compound having two benzene rings is 50 to 100 parts by mass with respect to the total 100 parts by mass of the aromatic amine compound.

8. The liquid resin composition for underfill according to claim 1, wherein Component (B) comprises an aromatic amine compound having one aromatic ring and/or an aromatic amine compound having two aromatic rings, the aromatic amine compound having two benzene rings is 50 to 100 parts by mass with respect to the total 100 parts by mass of the aromatic amine compound, and the time required for the viscosity to become 1 Pa·s at a pressure of 100 Pa and at a temperature of 100° C. is 40 to 180 minutes.

9. The liquid resin composition for underfill according to claim 7, wherein the average volatilization rate when kept for two hours at a pressure of 100 Pa and at a temperature of 100° C. is 0 to 1.3 mass %/hour.

10. The liquid resin composition for underfill according to claim 8, wherein the average volatilization rate when kept for two hours at a pressure of 100 Pa and at a temperature of 100° C. is 0 to 1.3 mass %/hour.

11. The liquid resin composition for underfill according to claim 7, wherein the average volatilization rate of Component (B) when kept for two hours at a pressure of 100 Pa and at a temperature of 100° C. is 0 to 10 mass %/hour.

12. The liquid resin composition for underfill according to claim 8, wherein the average volatilization rate of Component (B) when kept for two hours at a pressure of 100 Pa and at a temperature of 100° C. is 0 to 10 mass %/hour.

13. The liquid resin composition for underfill according to claim 1, wherein Component (A) is at least one selected from the group consisting of a bisphenol F type epoxy resin and a naphthalene type epoxy resin, and the time required for the viscosity to become 1 Pa·s at a pressure of 100 Pa and at a temperature of 100° C. is 40 to 180 minutes.

14. The liquid resin composition for underfill according to claim 1, wherein Component (A) is at least one selected from the group consisting of a bisphenol F type epoxy resin and a naphthalene type epoxy resin, Component (B) comprises an aromatic amine compound having one aromatic ring and/or an aromatic amine compound having two aromatic rings, and the aromatic amine compound having two benzene rings is 50 to 100 parts by mass with respect to the total 100 parts by mass of the aromatic amine compound.

15. The liquid resin composition for underfill according to claim 1, wherein Component (A) is at least one selected from the group consisting of a bisphenol F type epoxy resin and a naphthalene type epoxy resin, Component (B) comprises an aromatic amine compound having one aromatic ring and/or an aromatic amine compound having two aromatic rings, the aromatic amine compound having two benzene rings is 50 to 100 parts by mass with respect to the total 100 parts by mass of the aromatic amine compound, and the time required for the viscosity to become 1 Pa·s at a pressure of 100 Pa and at a temperature of 100° C. is 40 to 180 minutes.

16. The liquid resin composition for underfill according to claim 2, comprising 30 to 120 parts by mass of Component (B) and 160 to 400 parts by mass of Component (C) with respect to 100 parts by mass of Component (A).

17. The liquid resin composition for underfill according to claim 7, comprising 30 to 120 parts by mass of Component (B) and 160 to 400 parts by mass of Component (C) with respect to 100 parts by mass of Component (A).

18. The liquid resin composition for underfill according to claim 8, comprising 30 to 120 parts by mass of Component (B) and 160 to 400 parts by mass of Component (C) with respect to 100 parts by mass of Component (A).

19. A flip-chip mounted body sealed with the liquid resin composition for underfill as set forth in claim 8.

20. A method for manufacturing a flip-chip mounted body sealed with the liquid resin composition for underfill as set forth in claim 19.
